(19) United States
(12) Patent Application Publication
(10) Pub. No.: US 2009/0212807 A1
(43) Pub. Date: Aug. 27, 2009

(54) PROBE OF CANTILEVER PROBE CARD

(75) Inventors: Been-long Chen, Hsin-Chu City (TW); Huang-chih Chen, Hsin-Chu City (TW)

Correspondence Address: KIRTON AND MCCONKIE, 60 EAST SOUTH TEMPLE,, SUITE 1800, SALT LAKE CITY, UT, 84111, US

(73) Assignee: IPWORKS TECHNOLOGY CORP., Hsin-Chu (TW)

(21) Appl. No.: 12/182,784

(22) Filed: Jul. 30, 2008

(30) Foreign Application Priority Data
Feb. 21, 2008 (TW) 097106040

(51) Int. Cl. G01R 1/067

(52) U.S. Cl. 324/762

(57) ABSTRACT

A probe of a cantilever probe card (Epoxy probe card) is disclosed. The probe has a tip and a surface region extended from the tip of the probe about 5-10 mil is coated with a nano-film of high electro-conductive nanomaterial. The thickness of the nano-film is about 1-20 nm. Through the coating process, the nano-film coated on the probe of the cantilever probe card can efficiently provide the excellent advantages of no-clean, stable electro-conductivity, minimum overdrive force and longer usage lifetime for the probe of cantilever probe card. Accordingly, the yield of wafer testing can be improved and the frequency of cleaning the probe can be decreased. Furthermore, the total testing cost can be reduced.

### BACKGROUND OF THE INVENTION

1. Field of the Invention

The present invention relates to a probe of a probe card for a wafer probing test, and more particularly to a probe of a cantilever probe card having a nano-film of electro-conductive nanomaterial on the probe.

2. Description of Prior Art

A probe card is constructed by a multi-layer printed circuit board (PCB) which may include more than 30 layers. The probe card has complicated structure and provides a plurality of probes for being in contact with a plurality of electrical contacts (i.e. pads) on a wafer, respectively. Generally, a contact area between each of the probes and each of the electrical contacts of the wafer is smaller than a cross-sectional area of one hair. Before an integrated circuit (IC) die is packaged by encapsulant, the probe card can be used to test electrical functions of the IC die cut from a wafer, in order to remove defective dies and keep known good dies for the following packaging process. Thus, a wafer probing test is one of important processes in the integrated circuit fabrication, which affects the manufacture cost thereof.

The assembly and fabrication of the present cantilever probe card takes tremendous manpower and working hours. So, cost down cannot be achieved because mass production is not possible, either. For example, the procedure of fixing the probes with Epoxy ring needs to be done by human beings for confirming pad positions of the printed circuit board (PCB) of the probe card in advance. And then, fixing all the probes with Epoxy ring mounted on the printed circuit board (PCB) is done one by one. Finally, one ends of the probes are electrically connected with the printed circuit board (PCB) with solders and the other ends of the probes are employed for being in contact with the electrical contacts (i.e. pads) on the wafer. The foregoing complicated procedure is one key factor of influencing lifetime of a cantilever probe card.

Moreover, the increasing number of the probes consequently lowers coplanarity of the probes of the probe card and the pitch between the adjacent probes is the restriction of the whole cantilever probe card. Accordingly, maintaining good test yield and great test stability becomes quite difficult when tests for several to-be-tested dies are executed simultaneously.

Furthermore, the probes of the entire cantilever probe card must be fully in contact with a to-be-tested die, in order to ensure the test quality of the cantilever probe. Taking the cantilever probe card as example, the shape of the probe is a long cylinder, therefore, the tip of the probe will scratch the surface of the to-be-tested die. After the tip numerously scratch the surface of the to-be-tested die, the tip of the probe may be wetted with foreign matter (such as solder from the pad), the test quality may be lowered or the mis-test probability may be increased, to result in low test yield unexpectedly. Generally, for solving the foregoing problem, a minimum overdrive contact force must be applied to enforce the tip to tightly bear against the surface of the pad, so that the good contact condition and the great test yield and quality can be remained. Though applying a minimum overdrive contact force can be used to solve the foregoing problem and remain the great test yield. Nevertheless, the minimum overdrive contact force may damage other lower structure under the surface of the pad of the to-be-tested die. Particulaly for current technologies of advanced wafer processes (such as 0.13 μm, 90 nm, 65 nm, and etc.) are generally carried out on wafers made of fragile low-k dielectric material, the foregoing minimum overdrive contact force is hardly employed for the wafer probing test and the following package therefor because the fragile low-k dielectric material and ultra-low-k dielectric material are generally used in the aforesaid advanced wafer processes. The probing test therefor must prevent the low-k dielectric material and other lower structure/material thereof from being deformed or damaged. Although a cleaning method of the probes can be employed to solve the foregoing problem. However, with the gradually increasing number of the probes or the gradually decreasing pitch between the adjacent probes, the cleaning frequency of the probes may be considerably increased, disadvantages of consequentially lowering the uptime of test machines and shortening the lifetime of the probes appear to under the aforesaid gradual changes.

The foregoing solder-wetted problem is generally occurred on the probes of the cantilever probe card. Recently, although related manufacturers develop a kind of probe coated with a metal film capable of extending the lifetime thereof but the wetted problem still cannot be solved. As a result, the metal film still cannot enhance the test yield and the test stability.

### SUMMARY OF THE INVENTION

An object of the present invention is to provide a probe of a cantilever probe card, which is used to maintain the test quality of the wafer probing test, and to prevent the probe from being wetted with a to-be-tested die, so as to decrease the cleaning frequency of the probe, moreover, to enhance the uptime of test machines, and to increase the test yield of the dies for ultimately reducing the entire test cost.

For accomplishing aforesaid objective of the present invention, the present invention employs a probe of a cantilever probe card, which having a plurality of probes mounted thereon. The probe is made of a metal material and a nano-film of electro-conductive nanomaterial is coated on the probe. The nano-film of electro-conductive nanomaterial can be electro-conductive macromolecular material having no-clean characteristic and the thickness thereof is about 1-20 nm.

According to the present invention, the metal material for making the probe is selected from the group consisting of nickel, gold, copper, tungsten, rhenium, titanium, beryllium, palladium, platinum, silver, zinc, electro-conductive metal, and alloy thereof. A structure of the probe can be a metal micro-spring or a metal pin.

Moreover, the nano-film of electro-conductive nanomaterial is coated on the probe by an evaporated and chemical coating process and more exactly is coated on a surface of the probe vertically extended from a tip of the probe about 1-10 mil.

Comparing with prior arts, the present invention can efficiently provide an excellent advantages of no-clean, consisting and stable electro-conductivity, lower contact force and longer lifetime cantilever probe card because there is a nano-film of high electro-conductive nanomaterial coated on the probe tip. Moreover, the probe of the present invention maintains the test quality of the wafer probing test by preventing from generating excessive attraction force between each probe and each pad of the aforesaid to-be-tested die. Accordingly, the cleaning frequency of the probe can be decreased, moreover, the uptime of test machines can be increased and consequently, the test yield of the dies is increased for ultimately reducing the entire test cost.

### BRIEF DESCRIPTION OF THE DRAWINGS

FIG. 1 is a schematic view of a cantilever probe card according to a preferred embodiment of the present invention; and

FIG. 2 is an enlarged schematic view of a nano-film on a tip of the probe as shown in FIG. 1.

### DETAILED DESCRIPTION OF THE INVENTION

The present invention discloses a probe of a cantilever probe card, which having a plurality of probes mounted thereon. The probe is made of a metal material and a nano-film of electro-conductive nanomaterial is coated on the probe.

The aforesaid nano-film of electro-conductive nanomaterial can be polypyrrole, polyparaphenylene, polythiophene, polyaniline, combination thereof, or derivative thereof. The thickness of the nano-film of electro-conductive nanomaterial can be such as 1-20 nm. Further, the thickness of the nano-film of electro-conductive nanomaterial can be such as 1-5 nm.

The metal material can be nickel, gold, copper, tungsten, rhenium, titanium, beryllium, palladium, platinum, silver, zinc, electro-conductive metal, or alloy thereof. The rhenium-tungsten alloy or the beryllium-copper alloy can be illustrated. Furthermore, the probe can be a metal micro-spring or a metal pin.

Moreover, the nano-film of electro-conductive nanomaterial can be coated on the probe by an evaporated and chemical coating process. Specifically, the nano-film can be coated on the surface region of the probe vertically extended from a tip of the probe about 1-10 mil.

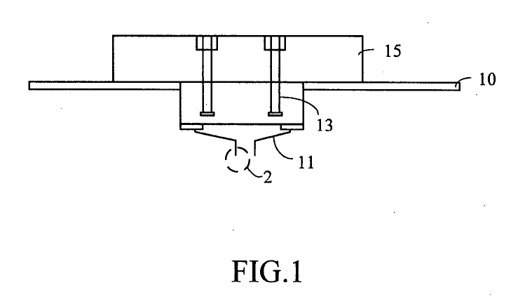

Please refer to FIG. 1, which is a schematic view of a cantilever probe card according to a preferred embodiment of the present invention. Dozens or even hundreds of probes 11 are mounted on the cantilever probe card by Epoxy related skills. Therefore, such kind of probe card is also named Epoxy probe card. As shown in FIG. 1, the cantilever probe card comprises a substrate 10, probes 11, a ceramic ring 13 and an enhanced body 15. The probes in FIG. 1 are cantilevered type probes and the central area of the substrate 10 is empty for positioning the plurality of probes 11. Moreover, the aforesaid substrate 10, probes 11, ceramic ring 13 and enhanced body 15 are designed, assembled and fabricated in many related procedures, such as, mounts for fixing, detail adjustment procedures for the control cables, probe positions and etc. to complete the whole cantilever probe card.

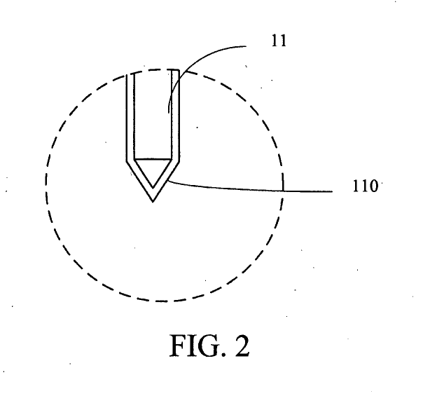

Please refer to FIG. 2, which is an enlarged schematic view of a nano-film on a tip of the probe shown in FIG. 1. According to the preferred embodiment of the present invention, the upper end (or the lower end) of each of the probes 11 is still coplanar in comparison with that of the original probe card. Because the thickness of the nano-film 110 is only about 1-20 nm or even thinner about 1-5 nm, the size of the probes 11 is not apparently increased and the test quality of high-frequency probing is not affected. According to the preferred embodiment of the present invention, the structure of the probes 11, as shown in the enlarged schematic view of FIG. 2, is not limited to the basic structure of the cantilever probe card. In the present invention, the tip of the probe 11 can be coated with the nano-film 110 of electro-conductive nanomaterial for realizing the accomplishment of the present invention.

In the present invention, the substrate 10 can be preferably a printed circuit board or a silicon substrate. The material of the cantilever probes 11 can be preferably electro-conductive metal or alloy. The foregoing alloy can be preferably Re—W alloy or Be—Cu alloy.

Furthermore, during transmitting electrical signals by the cantilever probes 11, the probes 11 having the nano-film 110 of electro-conductive nanomaterial can provide excellent no-clean property, so that the probes 11 can be easily in contact with tested locations of the to-be-tested die exactly without noise signal caused by wetted foreign matter. As a result, when the probes 11 transmit electrical signals, the noise signal can be prevented, so as to enhance the accuracy of signal transmission and the stability of wafer probing test.

Moreover, the present invention also can be applied for low-k dielectric material for advanced wafer processes (such as 0.13 μm, 90 nm, 65 nm, and etc.). Due to necessity to prevent the wafer probing test from deforming or damaging the low-k dielectric material and other lower structure/material thereof, the no-clean property accomplished by the probe 11 having the nano-film 110 coated thereon can satisfied requirements as aforementioned but without applying maximum overdrive force contact condition setting in the present invention. Consequently, the foregoing deformation/damage problem can be easily solved, and the test yield and quality can be efficiently enhanced.

In addition, in the present invention, the nano-film of the cantilever probe card is directly coated on the surface region of each of the probe tips by an evaporated and chemical coating process, so that the length of the nano-film on the probe can be precisely controlled by a coating fixture. In the preferred embodiment, the coating fixture can be easily designed according to simple parameters, such as, the size of the substrate (such as printed circuit board or silicon substrate), the relative pitch of the probes and the length of the probe tip. Thus, in the present invention, it is unnecessary to change the original structure of the probe card before finishing an advance process of forming the nano-film of the probes. Meanwhile, in the present invention, the coplanarity of the probes of the cantilever probe card are not changed by the nano-film process. As a result, the yield and the throughput of the nano-film process can be apparently enhanced, while the working hour and cost of the entire manufacture process can be also lowered.

As described above, according to the probe of the cantilever probe card provided by the present invention, the nano-film is formed on the probes of the cantilever probe card, so as to benefit increasing the integration density and the probe amount, and reducing the probe pitch. Meanwhile, the nano-film on the cantilever probe card of the present invention is manufactured precisely by the coating fixture and related process technologies, so that the manufacture cost of the nano-film can be lowered and the yield thereof can be enhanced.

The present invention provides a probe of a cantilever probe card, wherein a plurality of probes mounted on the cantilever probe card are applied to the wafer probing test of semiconductor industry. When traditional probes are used to carry out the wafer probing test, the tips of the probes may be wetted with solder from the pads of the to-be-tested die. To solve the problem, a surface region of the probe in the present invention is coated with a nano-film of electro-conductive nanomaterial for preventing from generating excessive attraction force between the probes and the to-be-tested die, so that the probes can provide excellent no-clean property. Consequently, the cleaning frequency of the probes can be decreased, the uptime of test machines can be increased, and the test yield of the dies can be raised, so as to reduce the entire test cost.

The present invention has been described with a preferred embodiment thereof and it is understood that many changes and modifications to the described embodiment can be carried out without departing from the scope and the spirit of the invention that is intended to be limited only by the appended claims.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A probe of a cantilever probe card, which having a plurality of probes mounted thereon, wherein the probe is made of a metal material and a nano-film of electro-conductive nanomaterial is coated on the probe.

2. The probe of claim 1, wherein the thickness of the nano-film of electro-conductive nanomaterial is about 1-20 nm.

3. The probe of claim 1, wherein the thickness of the nano-film of electro-conductive nanomaterial is about 1-5 nm.

4. The probe of claim 1, wherein the nano-film of electro-conductive nanomaterial is electro-conductive macromolecular material having no-clean characteristic.

5. The probe of claim 1, wherein the electro-conductive nanomaterial is selected from the group consisting of polypyrrole, polyparaphenylene, polythiophene, polyaniline, combination thereof, and derivative thereof.

6. The probe of claim 5, wherein the thickness of the nano-film of electro-conductive nanomaterial is about 1-20 nm.

7. The probe of claim 5, wherein the thickness of the nano-film of electro-conductive nanomaterial is about 1-5 nm.

8. The probe of claim 1, wherein the metal material is selected from the group consisting of nickel, gold, copper, tungsten, rhenium, titanium, beryllium, palladium, platinum, silver, zinc, electro-conductive metal, and alloy thereof.

9. The probe of claim 8, wherein the alloy is rhenium-tungsten alloy or beryllium-copper alloy.

10. The probe of claim 1, wherein the probe is a metal micro-spring or a metal pin.

11. The probe of claim 1, wherein the nano-film of electro-conductive nanomaterial is coated on the probe by an evaporated and chemical coating process.

12. The probe of claim 1, wherein the nano-film of electro-conductive nanomaterial is coated on a surface region of the probe vertically extended from a tip of the probe about 1-10 mil.
